(19) United States
(12) Patent Application Publication
(10) Pub. No.: US 2024/0303479 A1
(43) Pub. Date: Sep. 12, 2024

(54) MODEL TRAINING METHOD, PERFORMANCE PREDICTION METHOD, DEVICE, APPARATUS AND MEDIUM

(71) Applicant: BOE Technology Group Co., Ltd., Beijing (CN)

(72) Inventors: Quanguo Zhou, Beijing (CN); Jie Wang, Beijing (CN); Zhidong Wang, Beijing (CN); Cheng Zeng, Beijing (CN); Lirong Xu, Beijing (CN); Qing Zhang, Beijing (CN); Hao Tang, Beijing (CN); Lijia Zhou, Beijing (CN)

(73) Assignee: BOE Technology Group Co., Ltd., Beijing (CN)

(21) Appl. No.: 18/021,971

(22) PCT Filed: Mar. 30, 2022
(86) PCT No.: PCT/CN2022/084158

§ 371 Date: Feb. 17, 2023

(51) Int. Cl. G06N 3/08; G06N 3/044

(52) U.S. Cl. CPC G06N 3/08; G06N 3/044

(57) ABSTRACT

Disclosed is a model training method, a performance prediction method, an apparatus, a device and a medium, which relate to the technical field of display. The model training method includes acquiring a training sample set, wherein the training sample set includes: training design data and test data of a sample display device; inputting the training sample design data into a model to be trained, and training the model to be trained according to an output of the model to be trained and the training sample test data to obtain an initial prediction model; when the initial prediction model satisfies a pre-set condition, determining the initial prediction model as a performance prediction model; and a performance prediction model for predicting performance data of a target display device.

### TECHNICAL FIELD

The present disclosure relates to the technical field of display devices, in particular to a model training method, a performance prediction method, a model training device, a performance prediction device, a computing processing device, and a non-transitory computer-readable medium.

### BACKGROUND

In order to improve the success rate of product development and reduce the cost of product development and production, simulation software is often used to simulate thin film transistor liquid crystal displays (TFT-LCD) and organic light-emitting diode (AMOLED) display devices, based on the physical and chemical properties such as structure, materials, process, etc. to predict the performance of various aspects of a given design of display devices, and know the advantages and disadvantages of the design in advance before production and manufacturing.

There are many display technologies based on thin film transistor liquid crystal displays or organic light-emitting diodes (OLED), for example, quantum dot (QD) light-emitting display technology can use blue light OLED as a light source to excite red/green quantum dots in quantum dot light-converting film, and then excite red/green light to pass through color filter to form full-color display. Compared with conventional organic light-emitting diodes (OLED), a QD light-emitting display device has advantages of high color gamut, low energy consumption and adjustable spectrum. However, since quantum dot display devices, like other derivative display devices, are inconsistent with the physical structure of conventional organic light-emitting diodes, and have differences in light-emitting principles, it is impossible to directly use existing simulation software for simulation and prediction of performance, which hinders the development of new display technology products.

### SUMMARY

The present disclosure provides a model training method including:
acquiring a training sample set including: training sample design data and training sample test data: wherein the training sample design data includes: design data of a training sample display device, the training sample test data including: test data of the training sample display device;
inputting the training sample design data into a model to be trained, and training the model to be trained according to an output of the model to be trained and the training sample test data to obtain an initial prediction model;
determining the initial prediction model as a performance prediction model when the initial prediction model satisfies a pre-set condition: wherein the performance prediction model is used for predicting the performance data of the target display device according to the design data of the target display device.

In some embodiments of the present disclosure, the step of acquiring the training sample set includes:
acquiring design data of the training sample display device and test data of the training sample display device and pre-processing same; and
performing One-Hot encoding on pre-processed design data and pre-processed test data, respectively, to obtain the training sample design data and the training sample test data.

In some embodiments of the present disclosure, the step of performing One-Hot encoding on pre-processed design data and pre-processed test data, respectively, to obtain the training sample design data and the training sample test data includes:
performing One-Hot fixed value encoding on the pre-processed design data, and encoding fixed value data corresponding to the pre-processed design data as the training sample design data; and
in response to the pre-processed test data being fixed value data, performing One-Hot fixed value encoding on the pre-processed test data: in response to the pre-processed test data being quantized data, performing One-Hot quantization encoding on the pre-processed test data; encoding fixed value data and/or encoding quantized data corresponding to the pre-processed test data as the training sample test data.

In some embodiments of the present disclosure, acquiring design data of the training sample display device and test data of the training sample display device and pre-processing same includes:
performing clustering processing on the design data and the test data, so that data formats of the same type of design data are the same, and data formats of the same type of test data are the same;
removing erroneous data and duplicated data in the design data and the test data after the clustering processing, and obtaining missing data in the design data and the test data after the clustering processing to obtain complete design data and complete test data;
normalizing the complete design data and the complete test data to unify the data scale of the design data and the test data, and performing data association on the design data and the test data after the unification of the data scale; and
unifying formats and standards of the design data and the test data after the data association.

In some embodiments of the present disclosure, the step of inputting the training sample design data into a model to be trained, and training the model to be trained according to an output of the model to be trained and the training sample test data includes:
inputting the output of the model to be trained and the training sample test data into a pre-set loss function to obtain a loss value; and
aiming at minimizing the loss value, and adjusting parameters of the model to be trained.

In some embodiments of the present disclosure, the loss function is:

$$Loss = \frac{{\sum }_{i = 0}^{n} {( Y - {Y}^{′} )}^{2}}{n}$$

wherein Loss is the loss value, Y is the training sample test data, Y′ is an output value of the model to be trained, and n is a number of iterations.

In some embodiments of the present disclosure, the model to be trained is a fully-connected neural network or a transformer model.

In some embodiments of the present disclosure, there is at least one skip connection between different network levels of a fully-connected layer of the model to be trained:
wherein, the at least one skip connection is used for inputting output values of network levels separated by at least two layers into a pre-set network layer after being fused: the pre-set network layer is a deep network separated from a fused network layer by at least three layers.

In some embodiments of the present disclosure, the design data of the training sample display device includes at least one of: material data of the training sample display device, structural data of the training sample display device, pixel design data of the training sample display device, and process data of the training sample display device; and
the test data of the training sample display device includes at least one of: a quantum dot spectrum of the training sample display device, a half-peak width of the training sample display device, a blue light absorption spectrum of the training sample display device, a color shift of the training sample display device, a luminance decay of the training sample display device, a luminance of the training sample display device, a color gamut of the training sample display device, an external quantum efficiency of the training sample display device, and a lifetime of the training sample display device.

In some embodiments of the present disclosure, the step of determining the initial prediction model as a performance prediction model when the initial prediction model satisfies a preset condition includes:
inputting test sample design data into the initial prediction model to obtain initial prediction data: wherein the test sample design data is design data of a test sample display device;
obtaining a determined result according to an error value of the initial prediction data with respect to test sample test data, including: when the error value of the initial prediction data with respect to the test sample test data is less than or equal to a first pre-set threshold value, determining that the initial prediction model predicts accurately, otherwise determining that the initial prediction model predicts incorrectly: wherein the test sample test data is test data of the test sample display device;
obtaining a prediction accuracy rate of the initial prediction model according to at least one of the determined results; and
determining the initial prediction data as a performance prediction model when the prediction accuracy rate is greater than or equal to a second pre-set threshold value.

In some embodiments of the present disclosure, after the step of determining that the initial prediction model predicts accurately, further including:
regarding the test sample design data as the training sample design data, regarding the test sample test data as the training sample test data, and updating the training sample set; and
training the performance prediction model according to an updated training sample set.

The present disclosure also provides a performance prediction method including:
acquiring design data of a target display device;
inputting design data of the target display device into a performance prediction model to obtain test data of the target display device: wherein the performance prediction model is trained using the model training method as described in any one of the above embodiments.

In some embodiments of the present disclosure, the target design data is determined to be target hardware design data when the test data for the target display device is above a pre-set performance threshold.

The present disclosure further provides a model training device including:
a sample acquisition unit for acquiring a training sample set including: training sample design data and training sample test data: wherein the training sample design data includes: design data of a training sample display device, the training sample test data including: test data of the training sample display device;
a training unit for inputting the training sample design data into a model to be trained, and training the model to be trained according to an output of the model to be trained and the training sample test data to obtain an initial prediction model;
a model generation unit for determining the initial prediction model as a performance prediction model when the initial prediction model satisfies a pre-set condition: wherein the performance prediction model is used for predicting the performance data of the target display device according to the design data of the target display device.

The present disclosure further provides a performance prediction device including:
a design acquisition unit for acquiring design data of a target display device;
a prediction unit for inputting design data of the target display device into a performance prediction model to obtain test data of the target display device: wherein the performance prediction model is trained using the model training method as described in any one of the above embodiments.

The present disclosure also provides a computing processing device including:
a memory in which a computer readable code is stored;
one or more processors that, when executed by the one or more processors, perform the method for any of the embodiments described above.

The present disclosure also provides a non-transitory computer-readable medium having computer-readable code stored thereon that, when executed on a computing processing device, causes the computing processing device to perform a method as described in any of the embodiments above.

The above description is only an overview of the technical solution of the present disclosure. In order to better understand the technical means of the present disclosure, it can be implemented according to the contents of the specification, and in order to make the above and other purposes, features and advantages of the present disclosure more obvious and understandable, the specific implementation methods of the present disclosure are listed below.

### BRIEF DESCRIPTION OF THE DRAWINGS

In order to more clearly explain the embodiments of the present disclosure or the technical solutions in related art, the following will briefly introduce the drawings that need to be used in the embodiments or the description of the prior art. It is obvious that the drawings in the following description are only some embodiments of the present disclosure. For ordinary technicians in the art, other drawings can also be obtained from these drawings without any creative work.

FIG. 1 schematically illustrates a flow chart of the steps of the model training method according to the present disclosure;

FIG. 2 schematically illustrates a structural relationship diagram of a fully-connected layer skip connection according to the present disclosure:

FIG. 3 schematically illustrates a flow chart of the steps of a model training and application method according to the present disclosure:

FIG. 4 schematically illustrates a relationship diagram of model inputs and outputs according to the present disclosure:

FIG. 5 schematically illustrates a flow chart of a pre-process according to the present disclosure:

FIG. 6 schematically illustrates a flow chart of the steps of the performance prediction method according to the present disclosure:

FIG. 7 schematically illustrates a block diagram of a model training device according to the present disclosure; and

FIG. 8 schematically illustrates a block diagram of a performance prediction device according to the present disclosure.

### DETAILED DESCRIPTION

In order to make the purpose, technical scheme and advantages of the embodiments of the present disclosure clearer, the technical scheme in the embodiments of the present disclosure will be described clearly and completely in combination with the drawings in the embodiments of the present disclosure. Obviously, the described embodiments are part of the embodiments of the present disclosure, not all of them. Based on the embodiments in the present disclosure, all other embodiments obtained by ordinary technicians in the art without creative work fall within the scope of protection of the present disclosure.

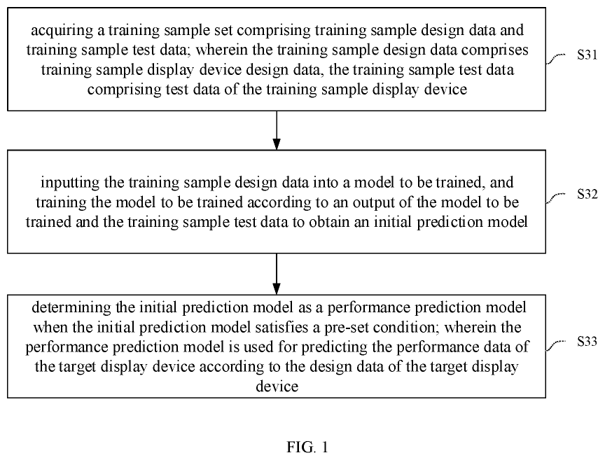

Reference is made to FIG. 1, which is a flow chart of the steps of the model training method according to the present disclosure. As shown in FIG. 1, the present disclosure provides a model training method including:

step S31, acquiring a training sample set including training sample design data and training sample test data: wherein the training sample design data includes design data of a training sample display device, the training sample test data including test data of the training sample display device.

In order to provide targeted training and subsequent more accurate application predictions, in an alternative embodiment, the training sample display device may be a display device of some specified type. In particular, the training sample display device may be a quantum dot light-emitting display device. Illustratively, the training sample display device may be a quantum dot photoluminescence (PL) display device with a combination structure of a blue OLED and quantum dots, and the training sample display device may also be a quantum dot electroluminescent (EL) light-emitting display device with a quantum dot structure.

In an alternative embodiment, the present disclosure may also provide multi-threaded model training, combining training for at least two types of display devices. When obtaining the multi-thread performance prediction model and applying the multi-thread performance prediction model to the performance prediction of the display device, when inputting the design data of the target display device, the type of the display device is automatically identified, and the multi-thread performance prediction model can predict using the corresponding thread. The training sample display devices include at least two types of display devices. Illustratively, the training sample display devices can be the quantum dot photoluminescent display devices and quantum dot electroluminescent display devices.

According to the present disclosure, the training sample design data and the training sample test data in the training sample set may be stored and used for training in the form of data pairs. Further, the test data of the training sample display device may be real test data corresponding to the design data of the training sample display device. Illustratively, the training sample design data may include a certain pixel arrangement, and the training sample test data corresponding thereto may be real performance test data for the display device under the pixel arrangement, such as a specific luminous lifetime value, a specific luminance value, a specific color gamut value, etc.

Step S32, inputting the training sample design data into a model to be trained, and training the model to be trained according to an output of the model to be trained and the training sample test data to obtain an initial prediction model.

In the present disclosure, the performance of each type of display device including the quantum dot display device can be predicted based on data, and therefore, the model to be trained can be a data type model, and further, the model to be trained can be a neural network model. In an alternative embodiment, the model to be trained is a fully connected neural network (FCN) or a transformer model.

Wherein training the model to be trained according to the output of the model to be trained and the training sample test data may include: adjusting the parameters of the model to be trained. Specifically, it may further include: adjusting weight parameters between network layers in the model to be trained. The initial prediction model may be an artificial intelligence algorithm model after adjusting the weight parameters between the network layers in the model to be trained.

Step S33, determining the initial prediction model as a performance prediction model when the initial prediction model satisfies a pre-set condition: wherein the performance prediction model is used for predicting the performance data of the target display device according to the design data of the target display device.

Among other things, the target display device may be the same type of display device entered with corresponding design data. That is, the training sample display device and the target display device may be the same type of display device. In particular, the training sample display device and the target display device may be the quantum dot light-emitting display devices. Illustratively, the training sample display device and the target display device may be the quantum dot photoluminescent display device with the combination structure of the blue OLED and the quantum dots, and the training sample display device and the target display device may also be the quantum dot electroluminescent display device of t quantum dot structure.

It should be noted that the same type referred to above has the same light-emitting principle, and is not limited to referring to the same specific dimensional structure or material properties of the display device.

The pre-set condition may be that the number of sample data pairs used for training the model to be trained reaches a pre-set sample size. Illustratively, the preset sample size may be 500 or 1000.

The preset condition may also be that the error value between the output of the model to be trained and the training sample test data is less than or equal to the preset error value. The preset error value may be 10%.

With the above-mentioned embodiments, the present disclosure provides a model training method, using data as a support, and training a data model according to design data and test data of a training sample display device to obtain a prediction model, which does not need to comprehensively consider the physical structure and material chemical properties of the display device, and also does not need to build a simulation prediction model according to the specific structure and light-emitting principle of the display device, and can achieve a more efficient performance prediction for the display device with a high prediction accuracy, and is not limited to the specific type, specific structure and light-emitting principle of the display device. Model learning and training can be performed for various types of display devices, with strong compatibility and applicability, and performance prediction can also be achieved for display devices that differ from conventional display devices in light-emitting principles such as quantum dot light-emitting display devices. Therefore, the present disclosure provides a model training method capable of learning and training based on a data model for various types of display devices, and the resulting performance prediction model can achieve performance prediction of a display device with strong compatibility and high efficiency without the light-emitting principle of the display device.

In particular, the present disclosure has the following advantages:

(1) firstly, according to the model training method provided by the present disclosure, the design data and test data of the training sample display device are used to train the model to be trained which is data-dependent model training, and is not limited to the specific type, specific structure and light-emitting principle of the display device: the model can be learned and trained for various types of display devices; and the obtained performance prediction model can be used for the performance prediction of corresponding types of display devices, with a wide range of applicability and strong compatibility.

(2) Secondly, according to the model training method provided by the present disclosure, a simulation prediction model is not required to be built according to the specific structure and light-emitting principle of a display device, but the material properties, structural properties and light-emitting principle of a display device such as quantum dot luminescence technology are relatively complicated; and on the basis of applying a data model for simulation prediction, for such a display device, the prediction accuracy rate would be higher than that of a simulation software based on an optical structure, and the prediction result would be closer to a real value.

(3) According to the model training method provided by the present disclosure, the internal physical structure and optical path relationship of a display device is not required to be considered, and a data model is directly trained based on real data to obtain a prediction model, wherein the prediction model directly gives a prediction value based on the input of the data, without comprehensively considering the physical structure and material chemical properties of the display device, and the prediction process is simpler, and thus a more efficient performance prediction can be achieved for the display device.

Considering the data nature of the data model used in the model to be trained, corresponding data processing needs to be performed on the training sample design data and the training sample test data to better complete the identification of the model to be trained. To this end, in an alternative embodiment, the present disclosure also provides a method for acquiring a training sample set, which includes:

step S311, acquiring design data of the training sample display device and test data of the training sample display device and pre-processing same.

Wherein the design data of the training sample display device and the test data of the training sample display device can be real design data and real test data obtained by measuring or testing the training sample display device for at least one type of display device. Illustratively lifetime data may be obtained by performing aging experiments on, for example, a training sample display device.

The pre-processing of the design data and the test data can be used to unify the format and standard of the data, so that the model to be trained can perform unified feature identification and processing.

Step S312, respectively performing One-Hot encoding on pre-processed design data and pre-processed test data to obtain the training sample design data and the training sample test data.

The One-Hot encoding takes the classification variables of the design data and the test data as the representation of binary vectors to improve the recognition efficiency of the model to be trained. Specifically, the One-Hot encoding first maps the class values of the design data and the test data to integer values, and then makes each integer value to be represented as a binary vector.

Illustratively, the encoding for the process class in the design data may be a spin coating process code of 001 and a printing process code of 010.

Thus, according to the present disclosure, the training sample design data and the training sample test data may be represented using the One-Hot encoding.

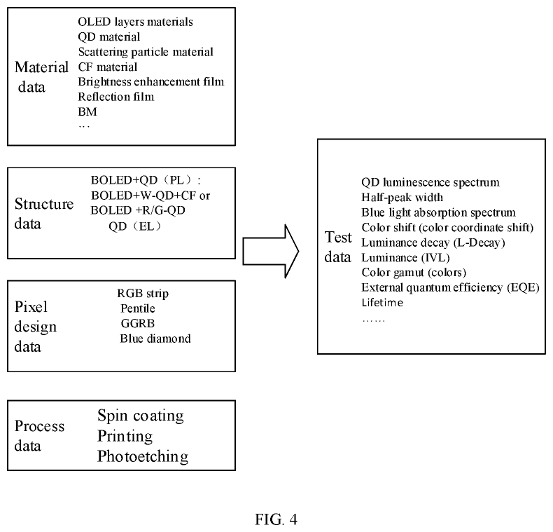

Reference is made to FIG. 4, a schematic illustration of a model input and output according to the present disclosure is shown. As shown in FIG. 4, specifically, in an alternative embodiment, for the case where the training sample display device is a quantum dot light-emitting display device, the design data of the training sample display device includes at least one of: material data of the training sample display device, structural data of the training sample display device, pixel design data of the training sample display device, and process data of the training sample display device.

The test data of the training sample display device includes at least one of: a quantum dot spectrum of the training sample display device, a half-peak width of the training sample display device, a blue light absorption spectrum of the training sample display device, a color shift of the training sample display device, a luminance decay of the training sample display device, a luminance of the training sample display device, a color gamut of the training sample display device, an external quantum efficiency of the training sample display device, and a lifetime of the training sample display device.

Further, in view of the fact that design data may be roughly classified and test data may need to be quantized, in an alternative embodiment, the present disclosure also provides a method for encoding design data and test data, including:

step S3131, performing One-Hot fixed value encoding on the pre-processed design data, and encoding fixed value data corresponding to the pre-processed design data as the training sample design data.

The fixed value encoding of the design data is to make each datum in the same design data type correspond to one code. The design data types may include: the material data, the structure data, the pixel design data, and the process data.

The present disclosure provides an example of performing the One-Hot fixed value encoding on the pre-processed design data:
the material data, the structure data, the pixel design data and the process data are fixed value data, and the fixed value data of the design data can be encoded. Illustratively, in the material data, there are 11 kinds of OLED materials in the blue light OLED device, and the quantum dot materials are divided into two types of red light and green light, wherein the spectrum of the red light material can be, from 610 nm to 650 nm, and each wave peak shift of 1 nm may be one kind of material, divided into 40 kinds of materials; and the spectrum of the green light material can be, from 530 nm to 550 nm, and each wave peak shift of 0.5 nm may be one kind of material, also divided into 40 kinds of materials, and thus there are 80 kinds of red and green quantum dot materials. There are 2 kinds of scattering materials: zirconia and titania, 3 kinds of red, green and blue color filter materials, 1 kind of brightness enhancement film and 1 kind of reflection film, and 1 kind of black mask (BM) material. The structure data has 3 values, the pixel design has 4 values, and the process data has 3 values. Thus, the fixed value data encoding the design data may have 109 values.

Step S3132, in response to the pre-processed test data being fixed value data, performing One-Hot fixed value encoding on the pre-processed test data: in response to the pre-processed test data being quantized data, performing One-Hot quantization encoding on the pre-processed test data: encoding fixed value data and/or encoding quantized data corresponding to the pre-processed test data as the training sample test data.

Wherein the fixed value encoding the test data includes making each datum in the same test data type correspond to one code. Wherein the type of test data subjected to fixed value encoding may include: the half-peak width, the color gamut, the external quantum efficiency, and the lifetime.

Quantization encoding of the test data includes making each data range in the same test data type correspond to one code. The types of test data that are subject to the quantization encoding may include: the quantum dot spectrum, the blue light absorption spectrum, the color shift, the luminance decay, and the luminance.

In particular, the total number of One-Hot fixed value encoding and One-Hot quantization encoding may be equal to the number of network channels of the fully-connected layer of the model to be trained.

The present disclosure provides an example of the One-Hot quantization encoding of the pre-processed test data:

in the test data, the quantum dot luminescence spectrum, the blue light absorption spectrum, the color shift, the luminance, the luminance decay and other quantitative data can be decomposed into 50 pieces of each type of data, and the processed quantization encoded data can be 250 pieces.

In the test data, the following data can be set to a fixed value: 1 fixed value for the half-peak width, 2 fixed values for the color gamut, 1 fixed value for the external quantum efficiency, and 1 fixed value for the lifetime. The number of the fixed value data encoding the test data may be 5.

Thus, by way of the above example, a total of 364 quantization encoded data and fixed value encoded data may be processed.

The One-Hot quantization encoding of the pre-processed test data includes quantization encoding a quantization fitting curve of a pre-set gradient value obtained by quantization. With reference to FIG. 4, further examples are given:

### I. One-Hot Fixed Value Encoding of the Design Data May Include:

### 1. Material Encoding

(1) The 11 OLED materials can be encoded as: 00000000001, 0000000010, 00000000100, . . . 01000000000, 10000000000;
(2) The 40 red materials in the quantum dot material are encoded from the spectrum 610 nm to 650 nm and can be encoded as: 000000 . . . 0001 (39 zeros in front of 1), 000000 . . . 0010 (38 zeros in front of 1), and . . . 10000 . . . 0000 (39 zeros behind 1);
(3) The green material can also be divided into 40 materials, and encoded as; 000000 . . . 0001 (39 zeros in front of 1), 000000 . . . 0010 (38 zeros in front of 1), . . . 10000 . . . 0000 (39 zeros behind 1);
(4) The red, green and blue RGB three-color codes of color filter (CF) materials are respectively: 001, 010, and 100;
(5) Brightness enhancement film material is encoded as: 1;
(6) Reflection film material is encoded as: 1; and
(7) Black mask is encoded as: 1.

### 2. Structure Data Encoding:

(1) The structural of blue OLED+white photoluminescence-quantum dot structure+color filter is encoded as: 001;
(2) The structural of blue OLED+red/green photoluminescence-quantum dot structure+color filter structure is encoded as: 010;
(3) The structural of the quantum dot light-emitting device is encoded as: 100.

### 3. Pixel Design Data:

(1) The RGB pixel arrangement is encoded as: 0001;
(2) The Pentile pixel arrangement is encoded as: 0010;
(3) The GGRB pixel arrangement is encoded as: 0100;
(4) The Blue diamond array pixel array is encoded as: 1000.

### 4. Process Data Encoding:

(1) The spin coating process is encoded as: 001;
(2) The printing process is encoded as: 010;
(3) The photolithography process is encoded as: 100.

### II. One-Hot Fixed Value Encoding of the Measured Data May Include:

1. The color gamut (colors) is encoded as: 01, 10;
2. The external quantum efficiency is encoded as: 1;
3. Lifetime is encoded as: 1;
4. The half-peak width is encoded as: 1.

### III. One-Hot Quantization Encoding of the Measured Data May Include:

1. The luminescence spectrum of quantum dots (divided into 50 pieces by quantization) is encoded as 000 . . . 0001 (there are 49 zeros in front of 1), 000 . . . 00010 (there are 48 zeros in front of 1), 1000 . . . 0000 (there are 49 zeros behind 1) from the start bit of the spectrum;
2. Blue light absorption spectrum (divided into 50 pieces by quantification): is encoded as 000 . . . 0001 (there are 49 zeros in front of 1), 000 . . . 00010 (there are 48 zeros in front of 1), . . . , 1000 . . . 0000 (there are 49 zeros behind 1) from the start bit of the spectrum;
3. Color shift encoding (divided into 50 pieces by quantization): is encoded as 000 . . . 0001 (there are 49 zeros in front of 1), 000 . . . 00010 (there are 48 zeros in front of 1), . . . , 1000 . . . 0000 (there are 49 zeros behind 1) from the start bit of the spectrum;
4. Luminance decay (L-decay) encoding (divided into 50 pieces by quantization) is encoded as 000 . . . 0001 (there are 49 zeros in front of 1), 000 . . . 00010 (there are 48 zeros in front of 1), . . . , 1000 . . . 0000 (there are 49 zeros behind 1) from the start bit of the spectrum;
5. Luminance encoding (divided into 50 pieces by quantification): is encoded as 000 . . . 0001 (there are 49 zeros in front of 1), 000 . . . 00010 (there are 48 zeros in front of 1), . . . 1000 . . . 0000 (there are 49 zeros behind 1) from the start bit of the spectrum.

Further, under the condition that the design data or the test data needs more parts which are accurate to the quantification, such as the area proportion of the pixel design, the One-Hot quantization encoding can also be performed on the pre-processed design data and/or more test data, the processed quantization encoded data and the fixed value encoded data can also be more, involving a greater amount of calculation, but obtaining a more accurate prediction result of the performance prediction model. In addition, it is possible to improve the accuracy of the quantization encoding, for example, by dividing the luminance encoding into 100 pieces by quantization, the amount of calculation involved is larger, but the prediction result of the performance prediction model obtained is more accurate.

Reference is made to FIG. 5, a schematic flow diagram of a pre-treatment according to the present disclosure is shown. As shown in FIG. 5, to further facilitate model recognition and processing of data, in an alternative embodiment, the present disclosure also provides a method for pre-processing the design data and the test data, which includes:

step S3121, performing clustering processing on the design data and the test data, so that the data format of the same type of design data is the same, and the data format of the same type of test data is the same.

Wherein the data formats correspond to different data types. The clustering processing includes aggregating the design data with the same data format and the test data with the same data format so that the same type of data can be integrated and processed. Illustratively, the half-peak width data of the training sample display device can be aggregated into one class, and the color shifts of the training sample display device can be aggregated into one class, with each having a data format.

Step S3122, removing erroneous data and duplicated data in the design data and the test data after the clustering processing, and obtaining missing data in the design data and the test data after the clustering processing to obtain complete design data and complete test data.

For an item of design data, under the condition that there are two types or more of identical test data, they are combined and processed: under the condition that there are two types or more of conflicting test data, the correct test data are selected.

Step S3123, normalizing the complete design data and the complete test data to unify the data scale of the design data and the test data, and performing data association on the design data and the test data after the unification of the data scale.

Unifying the data scale of the design data and the test data is to unify the starting point value and unit of the data for each type or data format. For example, the color shift data of different starting points can be unified as the color shift data of the same starting point; and the color shift data of different units can be unified as the color shift data of the same unit.

The data association includes: linking the design data and the test data into a corresponding data pair form: wherein the linking may be performed by marking a label.

Step S3124, unifying the formats and standards of the design data and the test data after the data association.

Unifying the format and standard are to unify the output file format and standard of the data. The design data and the test data can be saved and exported in the form of Excel files or csv files, which can be better used for identification and training of the model to be trained.

Based on the performances of neural network supervised learning, for the case where the model to be trained is a data type network model, in an alternative embodiment, the present disclosure also provides a method for training the model to be trained, which includes:

step S321, inputting the output of the model to be trained and the training sample test data into a pre-set loss function to obtain a loss value:

wherein, in an alternative embodiment, the loss function is:

$$Loss = \frac{{\sum }_{i = 0}^{n} {( Y - {Y}^{′} )}^{2}}{n}$$

wherein Loss is the loss value, Y is the training sample test data, Y′ is the output value of the model to be trained, and n is the number of iterations.

Step S322, aiming at minimizing the loss value, and adjusting parameters of the model to be trained.

In particular, adjusting the parameters of the model to be trained may include at least: adjusting connection weight parameters between various network layers in the model to be trained. The smaller the loss value, the better the model fits.

Parameter adjustments can also be made using optimizers. Illustratively, the optimizer may select an Adam optimizer with a learning rate of le-3, a batch size of 512 and the number of iterations of 160000; where the number of iterations is multiplied by 0.1 at 80000 and 100000. The dimension of the intermediate network layer is 256.

Wherein the model to be trained after adjusting parameters can be taken as an initial prediction model. Accordingly, when the loss value reaches a preset target loss value, the training of the model to be trained may be stopped, and the initial prediction model may be determined as a performance prediction model.

Through the above-mentioned embodiment, the model to be trained is supervised by the iteration of the loss function, and the parameters of the model to be trained are adjusted to minimize the loss value. The training process of the whole network is a process of continuously narrowing the loss value, which helps to improve the accuracy of the prediction result of the performance prediction model.

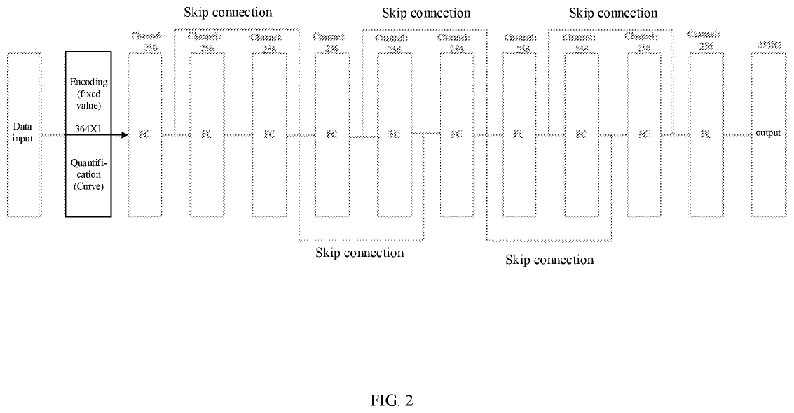

Reference is made to FIG. 2, which is a block diagram of a fully-connected layer skip connection according to the present disclosure. As shown in FIG. 2, to further improve the accuracy of the prediction results of the performance prediction model, in an alternative embodiment, the model to be trained may include a fully-connected neural network, with at least one skip connection between different network levels of the fully-connected layer of the model to be trained.

At least one of the skip connections is used for inputting output values of the network levels separated by at least two layers into a preset network layer after being fused.

The preset network layer is a deep network separated from the fused network layer by at least three layers.

As shown in FIG. 2, the dimension of the middle network layer of the fully-connected neural network may be 256, the number of channels corresponding to the number of input codes may be 364, and the number of channels corresponding to the number of output codes may be 255. Throughout the network, each neuron belongs to different layers, such as an input layer, a hidden layer, an output layer, etc. Data is input from the left input layer, calculated from the middle-hidden layer, and output from the right output layer. Each stage uses the output of the previous stage as input.

Illustratively, a skip connection may connect the outputs of the N^{th} and (N+2)^{th} layer networks in the fully-connected layer to the input of the (N+5)^{th} layer network.

Among other things, the fully-connected layer may include a 10-layer fully-connected (FC) network for feature recognition and processing of input data.

With the above-described embodiment, it is possible to effectively prevent gradient descent and further improve the accuracy of the prediction result of the obtained prediction model by using the skip connection between the fully-connected layers.

In an alternative embodiment, the present disclosure also provides a method for determining a performance prediction model, which includes:

step S331, inputting the test sample design data into an initial prediction model to obtain initial prediction data: wherein the test sample design data is design data of a test sample display device.

The test sample display device may be the same type of display device as the training sample display device and the target display device.

Step S332, obtaining a determined result according to the error value of the initial prediction data with respect to the test sample test data, including: when the error value of the initial prediction data with respect to the test sample test data is less than or equal to a first pre-set threshold value, determining that the initial prediction model predicts accurately, otherwise determining that the initial prediction model predicts incorrectly: wherein the test sample test data is test data of the test sample display device.

Illustratively, the first pre-set threshold value may be 10%, and it may be determined that the initial prediction model prediction predicts accurately when the error value of the initial prediction data with respect to the test sample test data is less than or equal to 10%, otherwise determining that the initial prediction model prediction predicts incorrectly.

Step S333, according to at least one of the determined results, obtaining the prediction accuracy rate of the initial prediction model.

At least one determined result can determine the prediction accuracy rate of the initial prediction model; and illustratively, when four determined results are prediction accuracy and one determined result is prediction incorrectly, the prediction accuracy rate of the initial prediction model is 80%.

Step S334, determining the initial prediction data as a performance prediction model when the prediction accuracy rate is greater than or equal to a second pre-set threshold value.

Illustratively, the second predetermined threshold may be 90%, and the initial prediction data may be determined to be a performance prediction model when the proportion of accuracy predicted by the initial prediction model is greater than 90%.

To further expand the training sample set and improve the accuracy, systematicness of training and verifying models, in an alternative embodiment, after the step of determining that the initial predictive model predicts accurately, the present disclosure also provides a method for training a performance prediction model, which includes:

step S41, regarding the test sample design data as training sample design data, regarding the test sample test data as training sample test data, and updating the training sample set.

The training sample set can be further enriched by taking test sample design data as training sample design data and test sample test data as training sample test data.

Step S42, training the performance prediction model according to the updated training sample set.

Through the above-mentioned embodiment, using the test sample design data and the test sample test data to train the performance prediction model is equivalent to using the verification method and the method for minimizing the model loss value to train the model comprehensively, which helps to further improve the prediction accuracy of the model.

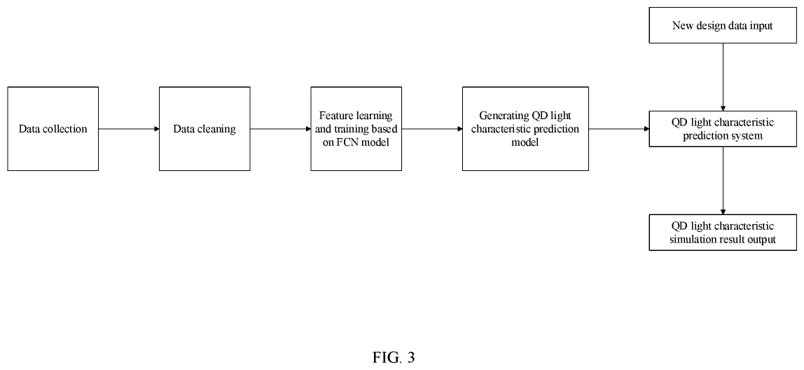

Reference is made to FIG. 3, which is a flow chart of the steps of a model training and application method according to the present disclosure. As shown in FIG. 3, in conjunction with the above embodiments, the present disclosure also provides a method for applying a model after training, for a quantum dot light-emitting display device, which includes:

step S101, collecting design data and test data of the sample display device:

step S102, cleaning the design data and test data of the sample display device, and unifying data formats and standards:

step S103, performing feature learning and training on the design data and the test data based on the FCN model:

step S104, generating a QD light characteristic prediction model:

step S105, obtaining a QD light characteristic prediction system based on the QD light characteristic prediction model; and

step S106, inputting the new design data into the QD light characteristic prediction system, and enabling the QD light characteristic prediction system to output a QD light characteristic simulation result corresponding to the new design data.

Through the above-mentioned embodiments, based on an artificial fully-connected artificial intelligence neural network model, data of materials, structures, designs and processes of a given QD display technology are cleaned, and the cleaned data are sent to the fully-connected neural network model for learning and training to generate a QD light characteristic prediction model, and the model is integrated into a QD light characteristic simulation system: then new design data, such as structures, materials, pixel designs and processes, are input into the system for simulation: finally, the performances of a QD light-emitting display device, such as the QD spectrum, the half-peak width, the color shift, the luminance decay, the blue light absorption spectrum, the luminance, the color gamut, the external quantum efficiency (EQE), lifetime and other indicators can be determined, thus improving the success rate of the QD display technology development and reducing the development and production cost of the QD display devices.

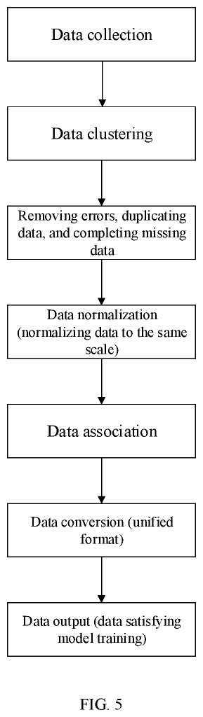

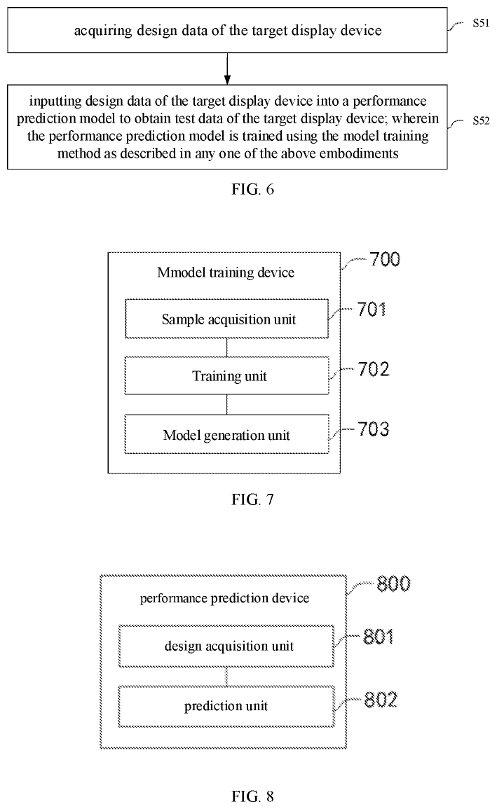

Reference is made to FIG. 6, which is a flow chart of the steps of the performance prediction method according to the present disclosure. As shown in FIG. 6, based on the same or similar inventive concept, the present disclosure also provides a performance prediction method including:

Step S51, acquiring design data of the target display device.

The design data of the target display device may also be in a data format similar to the design data of the same type of training sample display device, and subsequent pre-processing and encoding may be performed by the performance prediction model.

Step S52, inputting design data of the target display device into a performance prediction model to obtain test data of the target display device: wherein the performance prediction model is trained using the model training method as described in any one of the above embodiments.

Specifically, the design data of the target display device can be input in a numerical and/or One-Hot encoded manner, and the performance prediction model can perform data processing on its own and output corresponding test data.

In an alternative embodiment, the target design data is determined to be target hardware design data when the test data for the target display device is higher than a preset performance threshold.

Specifically, the preset performance threshold may be preset according to the performance requirements of the target display device, and at least one test data of the target display device corresponds to a corresponding preset performance threshold. Illustratively, when the luminance of the target display device is required to reach 500 nits and the test data of the luminance of the target display device is 515 nits, the target design data is determined as the target hardware design data.

Through the above-mentioned embodiment, the performance prediction of the display device is performed using the model trained in the above-mentioned embodiment, and the efficiency of performance prediction of the display device is improved without using a simulation model built according to the specific construction of the display device and the light-emitting principle, and the performance prediction can also be achieved for a display device having a light-emitting principle different from that of a conventional display device, such as a quantum dot light-emitting display device.

Referring to FIG. 7, a block diagram of a model training device according to the present disclosure is shown. As shown in FIG. 7, based on the same or similar inventive concept, the present disclosure also provides a model training device 700 including:
a sample acquisition unit 701 for acquiring a training sample set including: training sample design data and training sample test data: wherein the training sample design data includes: design data of a training sample display device, the training sample test data including: test data of the training sample display device;
a training unit 702 for inputting the training sample design data into a model to be trained, and training the model to be trained according to the output of the model to be trained and the training sample test data to obtain an initial prediction model; and
a model generation unit 703 for determining the initial prediction model as a performance prediction model when the initial prediction model satisfies a pre-set condition; wherein the performance prediction model is used for predicting the performance data of the target display device according to the design data of the target display device.

The model training device may use a central processing unit (CPU) chip or a microcontroller unit (MCU) chip as the information processing device, wherein the above-mentioned chip may burn a program for training the model, so that the model training device realizes the functions of the present disclosure, and the related art may be used for the implementation of these functions.

Referring to FIG. 8, a block diagram of a performance prediction device according to the present disclosure is shown. As shown in FIG. 8, based on the same or similar inventive concept, the present disclosure also provides a performance prediction device 800 including:
a design acquisition unit 801 for acquiring design data of a target display device;
a prediction unit 802 for inputting design data of the target display device into a performance prediction model to obtain test data of the target display device: wherein the performance prediction model is trained using the model training method as described in any one of the above embodiments.

The performance prediction device may use a central processing unit (CPU) chip or a microcontroller unit (MCU) chip as the information processing device, wherein the above-mentioned chip may burn a program for the performance prediction device, so that the performance prediction device realizes the functions of the present disclosure, and the prior art may be used for the implementation of these functions.

Based on the same or similar inventive concept, the present disclosure also provides a computing processing device including:
a memory in which a computer readable code is stored;
one or more processors that, when executed by the one or more processors, perform the method for any of the embodiments described above.

Based on the same or similar inventive concepts, the present disclosure also provides a non-transitory computer-readable medium having computer-readable code stored thereon that, when executed on a computing processing device, causes the computing processing device to perform a method as described in any of the embodiments above.

Each embodiment in the specification is described in a progressive manner. Each embodiment focuses on the differences from other embodiments. The same and similar parts between each embodiment can be referred to each other.

Finally, it should also be noted that in the specification, relational terms such as the first and second are only used to distinguish one entity or operation from another entity or operation, and do not necessarily require or imply any such actual relationship or order between these entities or operations. Moreover, the terms “including”, “comprising” or any other variation thereof are intended to cover non-exclusive inclusion, so that a process, method, commodity or equipment that includes a series of elements not only includes those elements, but also includes other elements that are not explicitly listed, or also includes elements inherent in such process, method, commodity or equipment. In the absence of further restrictions, the elements defined by the statement “including a . . . ” do not exclude the existence of other identical elements in the process, method, commodity or equipment including the elements.

The above describes in detail a model training method, a performance prediction method, a model training device, a performance prediction device, a computing processing device and a non-transitory computer-readable medium provided by the present disclosure. Specific examples are used in the specification to describe the principles and implementation of the present disclosure. The above examples are only used to help understand the methods and core ideas of the present disclosure. At the same time, for those skilled in the art, according to the idea of the present disclosure, there will be changes in the specific implementation mode and application scope. To sum up, the content of the specification should not be understood as a limitation of the present disclosure.

Those skilled in the art will easily think of other embodiments of the present disclosure after considering the description and practicing the invention disclosed herein. The present disclosure is intended to cover any variant, use or adaptive change of the present disclosure. These variants, uses or adaptive changes follow the general principles of the present disclosure and include the common knowledge or commonly used technical means in the technical field not disclosed in the present disclosure. The specification and the embodiments are only regarded as illustrative. The true scope and spirit of the present disclosure are indicated by the following claims.

It should be understood that the present disclosure is not limited to the precise structure described above and shown in the drawings, and various modifications and changes can be made without departing from its scope. The scope of the present disclosure is limited only by the appended claims.

The “one embodiment”, “embodiment” or “one or more embodiments” mentioned herein means that the specific features, structures or features described in combination with the embodiments are included in at least one embodiment of the present disclosure. In addition, please note that the word “in one embodiment” does not necessarily refer to the same embodiment.

A large number of specific details are described in the instructions provided here. However, it can be understood that the embodiments of the present disclosure can be practiced without these specific details. In some examples, the well-known methods, structures and techniques are not shown in detail so as not to obscure the understanding of the specification.

In the claims, any reference symbol between brackets shall not be constructed as a restriction on the claims. The word “including” does not exclude the existence of elements or steps not listed in the claims. The word “one” or “one” before a component does not exclude the existence of multiple such components. The present disclosure can be realized by means of hardware including several different elements and by means of a properly programmed computer. In the unit claims that list several devices, several of these devices can be embodied by the same hardware item. The use of the first, second, and third words does not indicate any order. These words can be interpreted as names.

Finally, it should be noted that the above embodiments are only used to illustrate the technical solution of the present disclosure, not to limit it. Although the present disclosure has been described in detail with reference to the preceding embodiments, those skilled in the art should understand that they can still modify the technical solutions recorded in the preceding embodiments or replace some of the technical features equally. These modifications or substitutions do not make the essence of the corresponding technical solutions separate from the spirit and scope of the technical solutions of the embodiments of the present disclosure.

1. A model training method, comprising:
acquiring a training sample set comprising training sample design data and training sample test data; wherein the training sample design data comprises design data of a training sample display device, the training sample test data comprising test data of the training sample display device;
inputting the training sample design data into a model to be trained, and training the model to be trained according to an output of the model to be trained and the training sample test data to obtain an initial prediction model; and
determining the initial prediction model as a performance prediction model when the initial prediction model satisfies a pre-set condition; wherein the performance prediction model is used for predicting the performance data of the target display device according to the design data of the target display device.

2. The model training method according to claim 1, wherein the step of acquiring the training sample set comprises:
acquiring design data of the training sample display device and test data of the training sample display device and pre-processing same; and
performing One-Hot encoding on pre-processed design data and pre-processed test data, respectively, to obtain the training sample design data and the training sample test data.

3. The model training method according to claim 2, wherein the step of performing One-Hot encoding on pre-processed design data and pre-processed test data, respectively, to obtain the training sample design data and the training sample test data comprises:
performing One-Hot fixed value encoding on the pre-processed design data, and encoding fixed value data corresponding to the pre-processed design data as the training sample design data; and
in response to the pre-processed test data being fixed value data, performing One-Hot fixed value encoding on the pre-processed test data; in response to the pre-processed test data being quantized data, performing One-Hot quantization encoding on the pre-processed test data; encoding fixed value data and/or encoding quantized data corresponding to the pre-processed test data as the training sample test data.

4. The model training method according to claim 2, wherein acquiring design data of the training sample display device and test data of the training sample display device and pre-processing same comprises:
performing clustering processing on the design data and the test data, so that data formats of the same type of design data are the same, and data formats of the same type of test data are the same;
removing erroneous data and duplicated data in the design data and the test data after the clustering processing, and obtaining missing data in the design data and the test data after the clustering processing to obtain complete design data and complete test data;
normalizing the complete design data and the complete test data to unify the data scale of the design data and the test data, and performing data association on the design data and the test data after the unification of the data scale; and
unifying formats and standards of the design data and the test data after the data association.

5. The model training method according to claim 1, wherein the step of inputting the training sample design data into a model to be trained, and training the model to be trained according to an output of the model to be trained and the training sample test data comprises:
inputting the output of the model to be trained and the training sample test data into a pre-set loss function to obtain a loss value; and
aiming at minimizing the loss value, and adjusting parameters of the model to be trained.

6. The model training method according to claim 5, wherein the loss function is:
$$Loss = \frac{{\sum }_{i = 0}^{n} {( Y - {Y}^{′} )}^{2}}{n}$$
wherein Loss is the loss value, Y is the training sample test data, Y′ is an output value of the model to be trained, and n is a number of iterations.

7. The model training method according to claim 1, wherein the model to be trained is a fully-connected neural network or a transformer model.

8. The model training method according to claim 7, wherein there is at least one skip connection between different network levels of a fully-connected layer of the model to be trained;
wherein, the at least one skip connection is used for inputting output values of network levels separated by at least two layers into a pre-set network layer after being fused; the pre-set network layer is a deep network separated from a fused network layer by at least three layers.

9. The model training method according to claim 1, wherein the design data of the training sample display device comprises at least one of: material data of the training sample display device, structural data of the training sample display device, pixel design data of the training sample display device, and process data of the training sample display device; and
the test data of the training sample display device comprises at least one of: a quantum dot spectrum of the training sample display device, a half-peak width of the training sample display device, a blue light absorption spectrum of the training sample display device, a color shift of the training sample display device, a luminance decay of the training sample display device, a luminance of the training sample display device, a color gamut of the training sample display device, an external quantum efficiency of the training sample display device, and a lifetime of the training sample display device.

10. The model training method according to claim 1, wherein the step of determining the initial prediction model as a performance prediction model when the initial prediction model satisfies a preset condition comprises:
inputting test sample design data into the initial prediction model to obtain initial prediction data; wherein the test sample design data is design data of a test sample display device;
obtaining a determined result according to an error value of the initial prediction data with respect to test sample test data, comprising: when the error value of the initial prediction data with respect to the test sample test data is less than or equal to a first pre-set threshold value, determining that the initial prediction model predicts accurately, otherwise determining that the initial prediction model predicts incorrectly; wherein the test sample test data is test data of the test sample display device;
obtaining a prediction accuracy rate of the initial prediction model according to at least one of the determined results; and
determining the initial prediction data as a performance prediction model when the prediction accuracy rate is greater than or equal to a second pre-set threshold value.

11. The model training method according to claim 10, after the step of determining that the initial prediction model predicts accurately, further comprising:
regarding the test sample design data as the training sample design data, regarding the test sample test data as the training sample test data, and updating the training sample set; and
training the performance prediction model according to an updated training sample set.

12. A performance prediction method, comprising:
acquiring design data of a target display device; and
inputting design data of the target display device into a performance prediction model to obtain test data of the target display device; wherein the performance prediction model is trained by using the model training method according to claim 1.

13. The performance prediction method according to claim 1112, wherein the method further comprises:
determining target design data as target hardware design data when the test data of the target display device is higher than a preset performance threshold.

14-15. (canceled)

16. A computing processing device, comprising:
a memory in which a computer-readable code is stored; and
one or more processors that, when executed by the one or more processors, performs the method according to claim 1.

17. A non-transitory computer-readable medium, having computer-readable code stored thereon which, when run on a computing processing device, causes the computing processing device to perform the method according to claim 1.

18. A computing processing device, comprising:
a memory in which a computer-readable code is stored; and
one or more processors that, when executed by the one or more processors, performs the method according to claim 12.

19. A non-transitory computer-readable medium, having computer-readable code stored thereon which, when run on a computing processing device, causes the computing processing device to perform the method according to claim 12.
